(19) United States
(12) Patent Application Publication
(10) Pub. No.: US 2024/0431163 A1
(43) Pub. Date: Dec. 26, 2024

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yi HE, Beijing (CN); Rong WANG, Beijing (CN); Xiangdan DONG, Beijing (CN); Fan HE, Beijing (CN); Jun YAN, Beijing (CN); Cong FAN, Beijing (CN)

(21) Appl. No.: 18/692,846

(22) PCT Filed: Jul. 5, 2023
(86) PCT No.: PCT/CN2023/105911

§ 371 Date: Mar. 18, 2024

(30) Foreign Application Priority Data
Jul. 15, 2022 (CN) 202210836718.9

(51) Int. Cl. H10K 59/131

(52) U.S. Cl. CPC H10K 59/131

(57) ABSTRACT

A display substrate includes a display region and a bezel region, wherein the bezel region includes a first bezel region located on a side of the display region. The display region includes plurality of sub-pixels, a plurality of first data lines, a plurality of second data lines, a plurality of first data connection lines and a plurality of second data connection lines. A plurality of first data lines are electrically connected with a plurality of second data connection lines through a plurality of first data connection lines. The first bezel region includes a plurality of first data lead wires, a plurality of second data lead wires, a plurality of lead transfer lines and at least one first power line. The first data lead wire includes a first lead wire and a second lead wire. The first lead wire is electrically connected with the second lead wire through lead transfer line.

### CROSS-REFERENCE TO RELATED APPLICATIONS

The present application is a U.S. National Phase Entry of International Application PCT/CN2023/105911 having an international filing date of Jul. 5, 2023, which claims priority to Chinese Patent Application No. 202210836718.9 filed to the CNIPA on Jul. 15, 2022 and entitled “Display Substrate and Display Apparatus”, and the contents disclosed in the above-mentioned applications are hereby incorporated as a part of this application.

### TECHNICAL FIELD

The present disclosure relates to, but is not limited to, the field of display technologies, in particular to a display substrate and a display apparatus.

### BACKGROUND

Organic Light Emitting Diodes (OLED's) and Quantum dot Light Emitting Diodes (QLED's) are active light emitting display devices and have advantages of self-illumination, a wide viewing angle, a high contrast ratio, low power consumption, an extremely high reaction speed, lightness and thinness, bendability, and a low cost, etc.

### SUMMARY

The following is a summary of subject matter described herein in detail. The summary is not intended to limit the protection scope of the claims.

Embodiments of the present disclosure provide a display substrate and a display apparatus.

In one aspect, a display substrate is provided in an embodiment, which includes a base substrate, a plurality of sub-pixels, a plurality of first data lines, a plurality of second data lines, a plurality of first data connection lines, a plurality of second data connection lines, a plurality of first data lead wires, a plurality of second data lead wires, a plurality of lead transfer lines and at least one first power line. The base substrate includes a display region and a bezel region, wherein the bezel region includes a first bezel region located on a side of the display region. The display region has a first boundary close to the first bezel region, the bezel region has a second boundary and a third boundary, and the second boundary and the third boundary are located on both sides of the first boundary in a first direction. A plurality of sub-pixels, a plurality of first data lines, a plurality of second data lines, a plurality of first data connection lines and a plurality of second data connection lines are located in the display region. A plurality of first data lines and a plurality of second data lines are configured to provide data signals to a plurality of sub-pixels. A plurality of first data connection lines extend along the first direction, and a plurality of first data lines, a plurality of second data lines, and a plurality of second data connection lines extend along the second direction, wherein the first direction intersects with the second direction. The plurality of first data lines are electrically connected with the plurality of second data connection lines through the plurality of first data connection lines. The plurality of first data lines are located on a side of the plurality of second data lines and the plurality of second data connection lines close to the second boundary or the third boundary in the first direction. A plurality of first data lead wires, a plurality of second data lead wires, a plurality of lead transfer lines and at least one first power line are located in the first bezel region. The plurality of first data lead wires are electrically connected with the plurality of second data connection lines, and the plurality of second data lead wires are electrically connected with the plurality of second data lines. The at least one first power line is configured to provide a power signal to the plurality of sub-pixels. at least one of the plurality of first data lead wires includes a first lead wire and a second lead wire, wherein the first lead wire is electrically connected with the second lead wire through the lead transfer line electrically connected with the second data connection line, the lead transfer line extends at least partially along the first direction, and the second lead wire is located on a side of the second data lead wire close to the second boundary or the third boundary in the first direction. An orthographic projection of at least one of the plurality of lead interconnection wires on the base substrate is overlapped with an orthographic projection of the first power line on the base substrate.

In some exemplary implementations, the first power line includes, at least, a first trace; wherein the first trace has a plurality of openings, and an orthographic projection of a connection position of the first lead wire with the lead transfer line on the base substrate is within an orthographic projection range of the openings on the base substrate.

In some exemplary implementations, at least part of segments of the first data lead wires and at least part of segments of the second data lead wires are located on a side of the first trace close to the base substrate, and the lead transfer lines are located on a side of the first trace away from the base substrate.

In some exemplary implementations, at least an organic insulation layer is disposed between the lead transfer line and the first trace.

In some exemplary implementations, the first lead wire is electrically connected to the lead transfer line through a first connection electrode located within the opening, and an orthographic projection of the first connection electrode on the base substrate is not overlapped with an orthographic projection of the first trace on the base substrate.

In some exemplary implementations, the first connection electrode and the first trace are in a same layer structure.

In some exemplary implementations, orthographic projections of the first data lead wire and the second data lead wire on the base substrate are overlapped with the orthographic projection of the first traces on the base substrate.

In some exemplary implementations, the first power line further includes a second trace located on a side of the first trace away from the base substrate, the second trace is electrically connected with the first trace, and an orthographic projection of the second trace on the base substrate is not overlapped with orthographic projections of the opening of the first traces on the base substrate.

In some exemplary implementations, the second trace and the lead transfer line are in a same layer structure.

In some exemplary implementations, at least one insulation layer is disposed between the first trace and the second trace, at least part of the first trace is in direct contact with the second trace, and the orthographic projection of the second trace on the base substrate covers at least part of a boundary of the at least one insulation layer.

In some exemplary implementations, the at least one insulation layer includes an inorganic insulation layer and an organic insulation layer, wherein the inorganic insulation layer is located on a side of the organic insulation layer close to the base substrate

In some exemplary implementations, the display substrate has a first centerline in the first direction. The plurality of first data lines are located on a side of the plurality of second data lines and the plurality of second data connection lines away from the first centerline, in the first direction, and the plurality of second lead wires are located on a side of the second data lead wires away from the first centerline, in the first direction.

In some exemplary implementations, the display region includes a first area and a second area located on both sides of the first centerline. In the first area or the second area, a second data connection line to which a first data line away from the first centerline is electrically connected is located on a side close to the first centerline of a second data connection line to which a first data line close to the first centerline is electrically connected.

In some exemplary embodiments, the display region includes a first area and a second area located on both sides of the first center line; In the first area or the second area, a second data connection line electrically connected to a first data line remote from the first center line is located on a side remote from the first center line of a second data connection line electrically connected to a first data line close to the first center line.

In some exemplary implementations, a lead transfer line to which a first lead wire close to the first centerline is electrically connected is located on a side close to the display region of a lead transfer line to which a first lead wire away from the first centerline is electrically connected.

In some exemplary implementations, a lead transfer line to which a first lead wire close to the first centerline is electrically connected is located on a side away from the display region of a lead transfer line to which a first lead wire away from the first centerline is electrically connected.

In some exemplary implementations, the plurality of lead interconnection wires are symmetrical with respect to the first centerline.

In some exemplary implementations, the first bezel region includes, at least, a first fan-out area, a bending area, a second fan-out area, and a first circuit area disposed in sequence in a direction away from the display region; the first circuit area includes, at least, a test circuit, and the first power line and the lead transfer line are at least located in the second fan-out area.

In some exemplary implementations, the first and second lead wires are located in the second fan-out area.

In some exemplary implementations, an orthographic projection of a connection position of the second lead wire with the lead transfer line on the base substrate and is not overlapped with the orthographic projection of the first power line on the base substrate.

In some exemplary implementations, a connection position of the second lead wire and the lead transfer line is located on a side of the first power line away from the bending area.

In another aspect, a display device is provided in an embodiment of the present disclosure, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a structure of a display apparatus according to at least one embodiment of the present disclosure.

FIG. 2 is a schematic diagram of a display substrate according to at least one embodiment of the present disclosure.

FIG. 3 illustrates schematically a cross-sectional view of a structure of a display region of a display substrate according to at least one embodiment of the present disclosure.

FIG. 4 is a wiring diagram of a display substrate according to at least one embodiment of the present disclosure.

FIG. 5 is an example of a wiring diagram of a display substrate according to at least one embodiment of the present disclosure.

FIG. 6 is a local wiring diagram of a second fan-out area according to at least one embodiment of the present disclosure.

FIG. 7 is a partial schematic diagram of a first bezel area according to at least one embodiment of the present disclosure.

FIG. 8 is a schematic diagram of a first data lead wire and a second data lead wire in FIG. 7.

FIG. 9 is a partial schematic diagram of a first source-drain metal layer in FIG. 7.

FIG. 10 is a partial schematic diagram of a second source-drain metal layer in FIG. 7.

FIG. 11 is a partial schematic view of the bending area and the second fan-out area in FIG. 7.

FIG. 12 is a partially enlarged view of a region A2 in FIG. 11.

FIG. 13A is a partially enlarged view of the first fan-out area in FIG. 12, after the second gate metal layer is formed.

FIG. 13B is a partially enlarged schematic view of the second fan-out area in FIG. 12, after the first source-drain metal layer is formed.

FIG. 13C is a partially enlarged view of the second fan-out area in FIG. 12, after the seventh insulation layer is formed.

FIG. 14A is a partially enlarged view along a P-P′ direction in FIG. 12.

FIG. 14B is a partially enlarged view along a Q-Q′ direction in FIG. 12.

FIG. 14C is a partially enlarged view along a U-U′ direction in FIG. 12.

FIG. 15 is a schematic diagram of connection between the lead transfer line and the second lead wire according to at least one embodiment of the present disclosure.

FIG. 16 is another wiring diagram of a display substrate according to at least one embodiment of the present disclosure.

FIG. 17 is another wiring diagram of a display substrate according to at least one embodiment of the present disclosure.

FIG. 18 illustrates schematically a partial view of the second fan-out area in FIG. 16 or FIG. 17.

FIG. 19 is a graph showing resistance changes of the plurality of data lead wires in the first bezel region.

FIG. 20 is a graph showing resistance changes of the plurality of data lead wires in the first bezel region after resistance compensation.

### DETAILED DESCRIPTION

The embodiments of the present disclosure will be described below with reference to the drawings in detail. Implementations may be implemented in multiple different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflicts.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and a mode of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, “electrical connection” includes connection of composition elements through an element with a certain electrical action. The “element having some electrical function” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the specification, “about” and “substantially” refer to that a boundary is not defined strictly and a case within a process and measurement error range is allowed. In the specification, “substantially the same” refers to a case where numerical values differ by less than 10%.

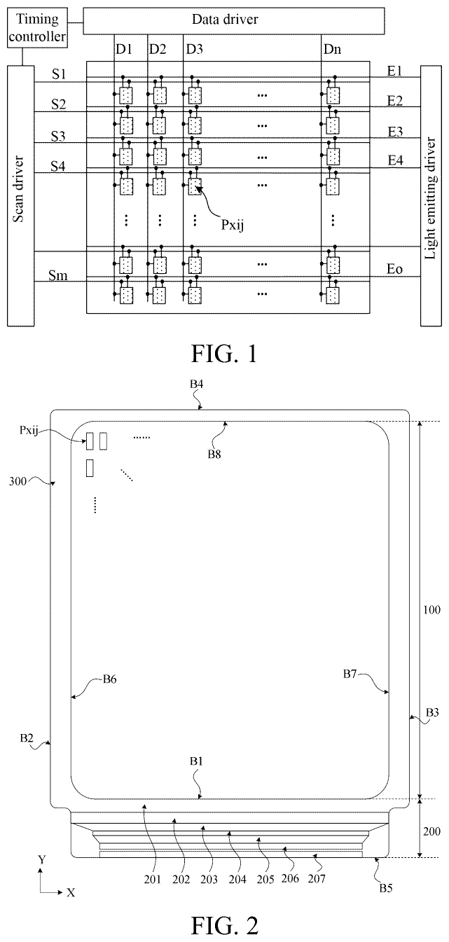

FIG. 1 is a schematic diagram of a structure of a display apparatus according to at least one embodiment of the present disclosure. As shown in FIG. 1, the display apparatus may include a timing controller, a data driver, a scan driver, a light emitting driver, and a display substrate. The timing controller is connected with the data driver, the scan driver, and the light emitting driver, respectively. The data driver is connected with a plurality of data lines (e.g., D1 to Dn), respectively, the scan driver is connected with a plurality of scan signal lines (e.g., S1 to Sm), respectively, and the light emitting driver is connected with a plurality of light emitting control lines (e.g., E1 to Eo), respectively, where n, m, and o may be natural numbers. The display substrate includes a pixel array that may include a plurality of the sub-pixels Pxij, where i, and j may be natural numbers. At least one of the sub-pixels Pxij may include a pixel circuit and a light emitting element connected with the pixel circuit. The pixel circuit may be connected with a scan line, a light emitting control line, and a data line, respectively.

In some exemplary embodiments, the timing controller may provide a gray-scale value and a control signal, which are suitable for a specification of the data driver, to the data driver; provide a clock signal, a scan start signal, and the like, which are suitable for a specification of the scan driver, to the scan driver; and provide a clock signal, a light emitting control start signal and the like, which are suitable for a specification of the light emitting driver, to the light emitting driver. The data driver may generate data voltages to be provided to the data lines D1, D2, D3 . . . and Dn using the gray-scale value and the control signal received from the timing controller. For example, the data driver may sample the gray-scale value by using a clock signal, and apply a data voltage corresponding to the gray-scale value to the data lines D1 to Dn in pixel rows. The scan driver may generate a scan signal to be provided to the scan lines S1, S2, S3, . . . , and Sm by receiving the clock signal, the scan start signal and the like from the timing controller. For example, the scan driver may sequentially provide the scan signals with an on-level pulse to the scan lines S1 to Sm. For example, the scan driver may be constructed in a form of a shift register, and may generate a scan signal in a manner of sequentially transmitting a scan start signal provided in a form of an on-level pulse to a next-stage circuit under control of the clock signal. The light emitting driver may receive the clock signal, the light emitting control start signal and the like from the timing controller to generate a light emitting control signal to be provided to light emitting control lines E1, E2, E3, . . . and Eo. For example, the light emitting driver may sequentially provide an emission signal with an off-level pulse to the light emitting signal lines E1 to Eo. For example, the light emitting driver may be constructed in a form of a shift register and generate a light emitting control signal in a manner of sequentially transmitting an light emitting control start signal provided in a form of an off-level pulse to a next-stage circuit under control of the clock signal.

FIG. 2 is a schematic diagram of a structure of a display substrate according to at least one embodiment of the present disclosure. As shown in FIG. 2, the display substrate may include a display region 100 and a bezel region on a periphery of the display region 100. The bezel region may include a first bezel region 200 on a side of the display region 100, and a second bezel region 300 on other sides of the display region 100. The first bezel region 200 and the second bezel region 300 are connected and surround the display region 100. In some examples, the display region 100 may be a planar region including a plurality of sub-pixels Pxij that form a pixel array. The plurality of sub-pixels Pxij may be configured to display a dynamic picture or a static image, and the display region 100 may be referred to as an Active Area (AA for short). In some examples, the display substrate may be a flexible substrate. Accordingly, the display substrate may be deformable, for example, crimped, bent, folded, or curled.

In some examples, as shown in FIG. 2, the display region 100 has a first boundary B1 proximate to the first bezel region 200, a sixth boundary B6, a seventh boundary B7, and an eighth boundary B8 proximate to the second bezel region 300. The first boundary B1 may be connected between the sixth boundary B6 and the seventh boundary B7, and the eighth boundary B8 may be connected between the sixth boundary B6 and the seventh boundary B7. The first boundary B1 and the eighth boundary B8 may be opposite along a second direction Y, and the sixth boundary B6 and the seventh boundary B7 may be opposite along a first direction X. The sixth boundary B6 and the seventh boundary B7 may be located on both sides of the first boundary B1 in the first direction X. The bezel region may have a second boundary B2, a third boundary B3, a fourth boundary B4, and a fifth boundary B5. The fourth boundary B4 may be connected between the second boundary B2 and the third boundary B3, and the fifth boundary B5 may be connected between the second boundary B2 and the third boundary B3. The second boundary B2 and the third boundary B3 are opposite in the first direction X, and the second boundary B2 and the third boundary B3 may be located on both sides of the first boundary B1 in the first direction X.

In some exemplary embodiments, as shown in FIG. 2, the first bezel region 200 may include a first fan-out area 201, a bending area 202, a second fan-out area 203, a first circuit area 204, a third fan-out area 205, a driver chip area 206, and a bonding pin area 207 that are disposed sequentially along the second direction Y away from the display region 100. The first fan-out area 201 may be connected to the display region 100 and includes, at least, a plurality of data fan-out lines that are configured to connect with the data lines of the display region 100 in a fan-out wiring manner. The bending area 202 is connected between the first fan-out area 201 and the second fan-out area 203, and the bending area 202 may include a composite insulation layer provided with a groove configured to bend the second fan-out area 203, the first circuit area 204, the third fan-out area 205, the driver chip area 206, and the bonding pin area 207 to a back surface of the display region 100. The second fan-out area 203 may include, at least, a plurality of data fan-out lines that are led out in a fan-out wiring manner. The second fan-out area 203 is connected between the bending area 202 and the first circuit area 204. The first circuit area 204 may include an electrostatic prevention circuit and a test circuit. The electrostatic prevention circuit may be configured to prevent electrostatic damage to the display substrate by eliminating static electricity. The test circuit may be configured to provide a data test signal to the data lines of the display region 100. The third fan-out area 205 may include, at least, a plurality of data fan-out lines which are led out in a fan-out wiring manner. The third fan-out area 205 is connected between the first circuit area 204 and the driver chip area 206. The driver chip area 206 may be provided with an Integrated Circuit (IC for short) that may be configured to connect with the plurality of data fan-out lines of the third fan-out area 205. The bonding pin area 207 may include a plurality of bonding pads that may be configured to bond with an external Flexible Printed Circuit (FPC for short). A connection trace may be provided between the driver chip area 206 and the bonding pin area 207.

In some exemplary embodiments, the second bezel region 300 may include a second circuit area, a power line area, a crack dam area and a cutting area which are disposed sequentially along the first direction X away from the display region 100. The first direction X intersects with the second direction Y. For example, the first direction X is perpendicular to the second direction Y. The second circuit area is connected to the display region 100 and may include, at least, a gate drive circuit that is connected with a first scan line, a second scan line, and a light emitting control line that are connected with the pixel circuit in the display region 100. The power line area is connected to the second circuit area, and may include, at least, a bezel power supply lead wire that extends along a direction parallel to an edge of the display region and is connected with a cathode in the display region 100. The crack dam area is connected to the power line area, and may include, at least, a plurality of cracks disposed on the composite insulation layer. The cutting area is connected to the crack dam area, and may include, at least, a cutting groove disposed on the composite insulation layer, wherein the cutting groove is configured for respectively cutting along the cutting groove by a cutting device after all film layers of the display substrate are manufactured.

In some exemplary embodiments, the first fan-out area 201 in the first bezel region 200 and the power line area in the bezel region 300 may be provided with a first isolation dam and a second isolation dam, the first isolation dam and the second isolation dam may extend along the direction parallel to the edge of the display region, thus forming an annular structure surrounding the display region 100. The edge of the display region is an edge of the display region 100 close to the first bezel region 200 or the second bezel region 300.

In some exemplary implementations, the display substrate may include a plurality of pixel units arranged in a matrix. At least one of the pixel units may include three sub-pixels emitting different colors. For example, one pixel unit may include a red sub-pixel, a green sub-pixel and a blue sub-pixel. Alternatively, at least one of the pixel units may include four sub-pixels, for example, may include a red sub-pixel, a blue sub-pixel, and two green sub-pixels, or may include a red sub-pixel, a green sub-pixel, a blue sub-pixel, and a white sub-pixel. Each of the sub-pixels may include a pixel circuit and a light emitting element. For example, a pixel circuit may be connected with a scan line, a data line, and a light emitting control line, respectively, and may be configured to receive a data voltage transmitted by the data line and output a corresponding current to a light emitting element under control of the scan line and the light emitting control line. The light emitting element in each sub-pixel is respectively connected to a pixel circuit of a sub-pixel where the light emitting element is located, and is configured to emit light with a corresponding brightness in response to a current output by the pixel circuit of the sub-pixel where the light emitting element is located. In some examples, a shape of the light emitting element of the sub-pixel may be a rectangle, a rhombus, a pentagon, or a hexagon. When one pixel unit includes three sub-pixels, light emitting elements of the three sub-pixels may be arranged in parallel in a horizontal direction, in parallel in a vertical direction or in a triangle manner. When one pixel unit includes four sub-pixels, light emitting elements of the four sub-pixels may be arranged in a diamond manner to form an RGBG pixel arrangement, or may be arranged in parallel in a horizontal direction, in parallel in a vertical direction or in a square manner. However, the present disclosure is not limited thereto.

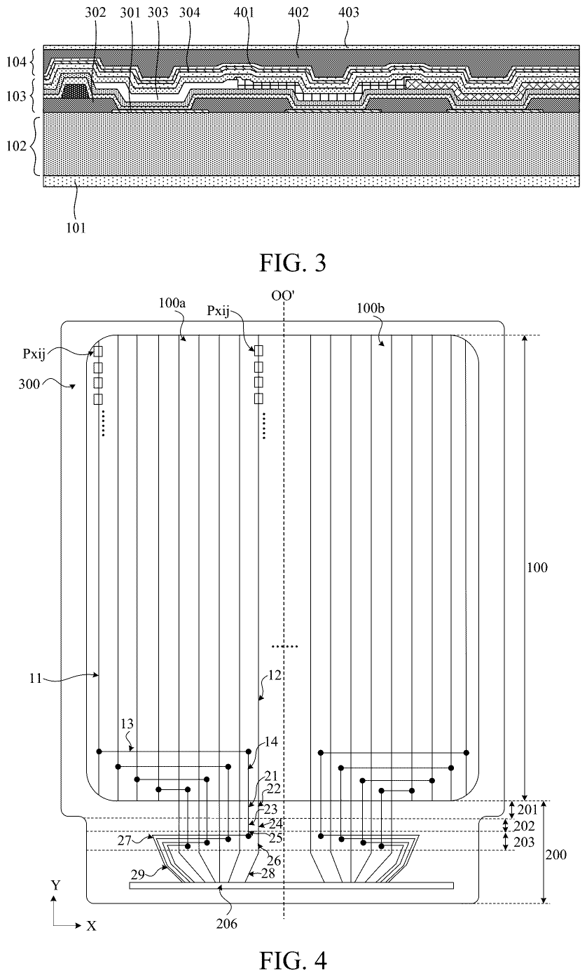

FIG. 3 illustrates schematically a cross-sectional view of a structure of a display region of a display substrate according to at least one embodiment of the present disclosure. FIG. 3 illustrates structures of three sub-pixels in the display region 100. In some examples, as shown in FIG. 3, in a direction perpendicular to the display substrate, the display substrate may include a base substrate 101, and a circuit structure layer 102, a light emitting structure layer 103, and an encapsulation structure layer 104 which are disposed on the base substrate 101, sequentially. In some possible implementations, the display substrate may include another film layer, such as a touch structure layer, which is not limited here in the present disclosure.

In some exemplary embodiments, as shown in FIG. 3, the base substrate 101 may be a flexible underlay substrate or a rigid underlay substrate. The circuit structure layer 102 of each sub-pixel may include a pixel circuit formed by a plurality of transistors and a storage capacitor. The light emitting structure layer 103 of each sub-pixel may include, at least, an anode 301, a pixel define layer 302, an organic light emitting layer 303 and a cathode 304. The anode 301 is connected with the pixel circuit, the organic light emitting layer 303 is connected with the anode 301, the cathode 304 is connected to the organic light emitting layer 303, and the organic light emitting layer 303 emits light in a corresponding color under driving of the anode 301 and the cathode 304. The encapsulation structure layer 104 may include a first encapsulation layer 401, a second encapsulation layer 402, and a third encapsulation layer 403 which are stacked, wherein the first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a laminated structure of an inorganic material/organic material/inorganic material, which may ensure that external water vapor cannot enter the light emitting structure layer 103.

In some exemplary embodiments, the organic emitting layer 303 may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In some examples, one or more of the hole injection layers, the hole transport layers, the electron block layers, the hole block layers, the electron transport layers and the electron injection layers of all sub-pixels may be respectively connected together to be a common layer. Emitting layers of adjacent sub-pixels may be overlapped slightly, or may be isolated from each other.

In some exemplary embodiments, the pixel circuit may have a structure of 3T1C, 4T1C, 5T1C, 5T2C, 6T1C, 7T1C, or 8T1C. In the above-mentioned circuit structure, T refers to a thin film transistor, C refers to a capacitor, a number before T represents a quantity of thin film transistors in the circuit, and a number before C represents a quantity of capacitors in the circuit. In some examples, the plurality of transistors in the pixel circuit may be P-type transistors or N-type transistors. Same type of transistors in the pixel circuit may simplify a process flow, reduce a process difficulty of the display substrate, and improve a yield of a product. In some other examples, the plurality of transistors in the pixel circuit may include P-type transistors and N-type transistors.

In some examples, low temperature poly-silicon thin film transistors, or oxide thin film transistors, or low temperature poly-silicon thin film transistors and oxide thin film transistors may be used as the plurality of transistors in the pixel circuit. An active layer of the low temperature poly-crystalline silicon thin film transistor is made of Low Temperature Poly-crystalline Silicon (LTPS for short), and an active layer of an oxide thin film transistor is made of an oxide semiconductor (Oxide). The low temperature poly-crystalline silicon thin film transistor has advantages such as a high migration rate and fast charging, and the oxide thin film transistor has advantages such as a low leakage current. The low temperature poly-crystalline silicon thin film transistor and the oxide thin film transistor being integrated on one display substrate, that is, an LTPS+Oxide (LTPO for short) display substrate, has advantages of both the low temperature poly-crystalline silicon thin film transistor and the oxide thin film transistor, such that low-frequency drive may be achieved, power consumption may be reduced, and display quality may be improved.

In some examples, the plurality of transistors of the pixel circuit including low temperature poly-silicon thin film transistors and oxide thin film transistors are taken as an example. In the direction perpendicular to the display substrate, the circuit structure layer may include a first semiconductor layer, a first insulation layer, a first gate metal layer, a second insulation layer, a second gate metal layer, a third insulation layer, a second semiconductor layer, a fourth insulation layer, a third gate metal layer, a fifth insulation layer, a first source-drain metal layer, a sixth insulation layer, a seventh insulation layer, a second source-drain metal layer, and an eighth insulation layer that are disposed on the base substrate, sequentially. In some examples, the first semiconductor layer may include an active layer of the low temperature poly-silicon thin film transistor of the pixel circuit. The first gate metal layer may include a gate of the low temperature poly-silicon thin film transistor of the pixel circuit and one of electrodes of the storage capacitor. The second gate metal layer may include another electrode of the storage capacitor of the pixel circuit. The second semiconductor layer may include the active layer of the oxide thin film transistor of the pixel circuit. The third gate metal layer may include a gate of the oxide thin film transistor of the pixel circuit. The first source-drain metal layer may include a plurality of connection electrodes. The second source-drain metal layer may include an anode connection electrode. The anode connection electrode of the second source-drain metal layer can be electrically connected with a corresponding anode of the light emitting structure layer through a via opened in the eighth insulation layer. In some examples, the first to sixth insulation layers may be inorganic insulation layers, and the seventh and eighth insulation layers may be organic insulation layers which may also be referred to as planar layers. However, the embodiment is not limited thereto.

With development of OLED display technologies, consumers are increasingly demanding higher-quality display effects from display products. Extremely narrow bezels have become a new trend in development of display products, hence the emphasis on minimizing bezels or even designing bezel-less displays is increasingly valued in OLED display product design. In a display substrate, the first bezel region generally includes a first fan-out area, a bending area, a second fan-out area, a first circuit area, a third fan-out area, a driver chip area, and a bonding pin area disposed sequentially along a direction away from the display region. Since a width (a length along the first direction X) of the first bezel region is less than a width (a length along the first direction X) of the display region, a signal line of the integrated circuit and the bonding pad in the first bezel region needs to be led into a wider display region by the fanout wiring manner through a fan-out area. The larger a width difference between the display region and the first bezel region, the more oblique lead wires in the fan-out area, and the larger a distance between the driver chip area and the display region, so that the first fan-out area occupies a larger space, resulting in greater difficulty in narrowing design of the first bezel region. To improve the above-mentioned situation, a data connection line can be provided in the display region, so that a data lead wire of the first bezel region is electrically connected with the data line through the data connection line, which can effectively reduce a length of the first fan-out area, thereby greatly reducing a dimension of a lower bezel. However, in a process of transferring the data line through the data connection line, an order of the data lead wires in the first bezel region is disturbed, so that the order of the data lead wires in the first bezel region is different from an order of the data lines in the display region, resulting in incompatibility with conventional integrated circuits, resistance abrupt change of a transmission trace for a data signal, and other problems.

A display substrate is provided in an embodiment of the disclosure, which includes a base substrate, a plurality of sub-pixels, a plurality of first data lines, a plurality of second data lines, a plurality of first data connection lines, a plurality of second data connection lines, a plurality of first data lead wires, a plurality of second data lead wires, a plurality of lead transfer lines and a first power line. The base substrate includes a display region and a bezel region, wherein the bezel region includes a first bezel region located on a side of the display region. The display region has a first boundary close to the first bezel region, the bezel region has a second boundary and a third boundary, and the second boundary and the third boundary are located on both sides of the first boundary in a first direction. A plurality of sub-pixels, a plurality of first data lines, a plurality of second data lines, a plurality of first data connection lines and a plurality of second data connection lines are located in the display region. A plurality of first data lines and a plurality of second data lines are configured to provide data signals to a plurality of sub-pixels. A plurality of first data connection lines extend along the first direction, and a plurality of first data lines, a plurality of second data lines, and a plurality of second data connection lines extend along the second direction. The first direction intersects with the second direction. For example, the first direction is perpendicular to the second direction. A plurality of first data lines are electrically connected with a plurality of second data connection lines through a plurality of first data connection lines. A plurality of first data lines are located on a side of a plurality of second data lines and a plurality of second data connection lines close to the second boundary or the third boundary in the first direction. A plurality of first data lead wires, a plurality of second data lead wires, a plurality of lead transfer lines and at least one first power line are located in the first bezel region. A plurality of first data lead wires are electrically connected with a plurality of second data connection lines. A plurality of second data lead wires are electrically connected with a plurality of second data lines. At least one first power line is configured to provide a power signal to a plurality of sub-pixels. At least one of the plurality of first data lead wires includes a first lead wire and a second lead wire. The first lead wire is electrically connected with the second lead wire through the lead transfer line. The first lead wire is electrically connected with the second data connection line. At least part of the lead transfer line extends along the first direction, and the second lead wire is located on the side of the second data lead wire close to the second boundary or the third boundary in the first direction. An orthographic projection of at least one of the plurality of lead transfer lines on the base substrate is overlapped with an orthographic projection of the first power line on the base substrate.

According to the display substrate provided in this embodiment, the first lead wire and the second lead wire are electrically connected in the first bezel region by the lead transfer line to adjust an order of the first data lead wires and the second data lead wires along the first direction, so that a supply order of the data signals or a test data signal in the first bezel region is consistent with an order of the first data lines and the second data lines in the display region, so as to achieve compatibility with conventional integrated circuits and save cost. Moreover, the resistance abrupt change of the transmission trace for the data signal can be improved to a certain extent.

In some exemplary implementations, the first power line may include, at least, a first trace. The first trace has a plurality of openings, and orthographic projection of a position where the first lead wire is connected with the lead transfer line on the base substrate can be located within an orthographic projection range of the openings on the base substrate. In this example, punch-hole design is performed on the first trace of the first power line to achieve an arrangement of the lead transfer line, which can reduce the influence on the first power line.

In some exemplary implementations, at least part of segments in the first data lead wires and at least part of segments in the second data lead wires may be located on a side of the first trace close to the base substrate, and the lead transfer line may be located on a side of the first trace away from the base substrate. In this example, an orthographic projection of the lead transfer line on the base substrate may be overlapped with orthographic projections of a plurality of data lead wires on the base substrate, and the data lead wires and the lead transfer lines are isolated by using the first trace of the first power line, which can effectively prevent mutual cross-talk between the traces.

In some exemplary implementations, at least an organic insulation layer may be provided between the lead transfer line and the first trace of the first power line. In this example, by providing the organic insulation layer between the lead transfer line and the first trace of the first power line, a dielectric layer between the lead transfer line and the first trace of the first power line can be increased, facilitating reduction of parasitic capacitance between them.

In some exemplary implementations, the first lead wire may be electrically connected with the lead transfer line through the first connection electrode. The first connection electrode may be located within the openings of the first trace, and an orthographic projection of the first connection electrode on the base substrate may be not overlapped with an orthographic projection of the first trace of the first power line on the base substrate. For example, the first connection electrode and the first trace may be in a same layer structure. However, the embodiment is not limited thereto. For example, the first lead wire may be directly electrically connected with the lead transfer line.

In some exemplary implementations, the first power line may further include a second line located on a side of the first trace away from the base substrate. The second trace is electrically connected with the first trace, and an orthographic projection of the second trace on the base substrate is not overlapped with the orthographic projections of the openings of the first trace on the base substrate. In this example, the area where the openings of the first trace are provided is a connection area between the lead transfer line and the first lead wire, and the first power line can employ a double-layer wiring in an area other than the connection area between the lead transfer line and the first lead wire. For example, the second trace and the lead transfer line may be in a same layer structure.

In some exemplary implementations, the first bezel region may include, at least, a first fan-out area, a bending area, a second fan-out area, and a first circuit area that are sequentially disposed in a direction away from the display region. The first circuit area includes, at least, a test circuit. The first power line and the lead transfer line can be located at least in the second fan-out area. In this example, the lead transfer line is disposed on the side of the first circuit area close to the display region, which is beneficial to adjust an order of the first data lead wire and the second data lead wire, thereby being compatible with conventional integrated circuits and reducing the cost. Moreover, it is beneficial to narrow the lower bezel. In other examples, the lead transfer line and the first power line may be located at least in the first fan-out area to enable order adjustment of the first data lead wire and the second data lead wire.

Solutions of the embodiments will be described below through some examples.

FIG. 4 is a wiring diagram of a display substrate according to at least one embodiment of the present disclosure. In some examples, as shown in FIG. 4, the display region 100 may include a plurality of first data lines 11 and a plurality of second data lines 12 extending in the second direction Y. The first data lines 11 may be electrically connected with a plurality of sub-pixels Pxij arranged along the second direction Y, and the first data lines 11 are configured to provide data signals to the plurality of sub-pixels Pxij. The second data lines 12 may be electrically connected with a plurality of sub-pixels Pxij arranged along the second direction Y, and the second data lines 12 are configured to provide data signals to the plurality of sub-pixels Pxij. A plurality of first data lines 11 and a plurality of second data lines 12 may be arranged along the first direction X. For example, a plurality of first data lines 11 may be located outside the plurality of second data lines 12 in the first direction X. As shown in FIGS. 2 and 4, a plurality of first data lines 11 are located on a side of a plurality of second data lines 12 close to the second boundary B2 and the third boundary B3 in the first direction X. The display substrate may have a first centerline OO′ in the first direction X. A plurality of second data lines 12 may be located on a side of a plurality of first data lines 11 close to the first centerline OO′.

In some examples, as shown in FIG. 4, the display region 100 may further include a plurality of first data connection lines 13 extending along the first direction X and a plurality of second data connection lines 14 extending along the second direction Y. A plurality of first data lines 11 may be electrically connected with a plurality of first data connection lines 13 in one-to-one correspondence, and a plurality of first data connection lines 13 may be electrically connected with a plurality of second data connection lines 14 in one-to-one correspondence. One first data line 11 may be electrically connected to one second data connection line 14 through a first data connection line 13. For example, one end of the first data connection line 13 is electrically connected with the first data line 11 and the other end of the first data connection line 13 is electrically connected with the second data connection line 14. The second data connection line 14 may be located on a side of the electrically connected first data line 11 close to the first centerline OO′ in the first direction X. A second data connection line 14 may be interposed between a plurality of second data lines 12 in the first direction X. For example, one second data connection line 14 may be arranged at intervals of four second data lines 12 in the first direction X. However, the embodiment is not limited thereto.

In some examples, as shown in FIG. 4, the display region 100 may include a first area (e.g. a left half area) 100a and a second area (e.g. a right area) 100b located on both sides of the first centerline OO′. In the first area 100a or the second area 100b, a length of a first data connection line 13 to which a first data line 11 away from the first centerline OO′ is electrically connected may be greater than a length of a first data connection line 13 to which a first data line 11 close to the first centerline OO′ is electrically connected. The first data connection line 13 to which the first data line 11 away from the first centerline OO′ is electrically connected may be located on a side away from a lower edge of the display region 100 of the first data connection line 13 to which the first data line 11 close to the first centerline OO′ is electrically connected, in the second direction Y. For example, the first region 100a and the second region 100b may be substantially symmetrical about the first centerline OO′. However, the embodiment is not limited thereto.

In some examples, as shown in FIG. 4, in either the first area 100a or the second area 100b, the second data connection line 14 to which the first data line 11 away from the first centerline OO′ is electrically connected may be located on a side close to the first centerline OO′ of the second data connection line 14 to which the first data line 11 close to the first centerline OO′ is electrically connected, in the first direction X. A length of the second data connection line 14 to which the first data line 11 away from the first centerline OO′ is connected may be greater than a length of the second data connection line 14 to which the first data line 11 close to the first centerline OO′ is electrically connected, along the second direction Y. In this example, taking the first area 100a of the display region 100 as an example, an arrangement order of the plurality of first data lines 11 from edge to center along the first direction X is opposite to an arrangement order of the second data connection lines 14 to which the plurality of first data lines 11 are interconnected from edge to center along the first direction X. The transferring mode of the first data line 11 shown in this example may be referred to as a reverse sequence insertion mode.

In some examples, the first data lines 11, the second data lines 12 and the second data connection lines 14 may be in a same layer structure. For example, all of the first data lines 11, the second data lines 12 and the second data connection lines 14 may be located in the second source-drain metal layer, and the first data connection line 13 may be located in the first source-drain metal layer. However, the embodiment is not limited thereto. For example, the first data lines 11, the second data lines 12 and the second data connection line 14 may be located in the first source-drain metal layer, and the first data connection line 13 may be located in the second source-drain metal layer. Alternatively, the first data line 13 may be located in the first gate metal layer, the second gate metal layer or the third gate metal layer.

In some examples, as shown in FIG. 4, the first fan-out area 201 may include a plurality of first data fan-out lines 21 and a plurality of second data fan-out lines 22. A first data fan-out line 21 may be electrically connected to a second data connection line 14 extending to the first fan-out area 201. A second data fan-out line 22 may be electrically connected to a second data line 12 extending to the first fan-out area 201. A plurality of first data fan-out lines 21 may be interspersed between a plurality of second data fan-out lines 22 in the first direction X. An arrangement order of a plurality of first data fan-out lines 21 and a plurality of second data fan-out lines 22 may be consistent with an arrangement order of a plurality of second data lines 12 and a plurality of second data connection lines 14 in the display region 100. For example, one first data fan-out line 21 may be arranged at intervals of four second data fan-out lines 22 in the first direction X. However, the embodiment is not limited thereto.

In some examples, the first data fan-out lines 21 and the second data fan-out lines 22 of the first fan-out area 201 may be located in the first gate metal layer or the second gate metal layer. Two adjacent data fan-out lines may be located in different conductive layers.

In this example, the first data lines 11 near the left and right edges of the display region 100 are led out from the display region 100 to the first fan-out area 201 through the first data connection lines 13 and the second data connection lines 14, so that the first data lines 11 and the second data lines 12 at the edges of the display region 100 can be led out collectively, thereby reducing an arrangement space occupied by the data fan-out lines of the first fan-out area 201, reducing a length of the first fan-out area 201 and reducing the dimension of the lower bezel.

In some examples, as shown in FIG. 4, the bending area 202 may include a plurality of first bend connection lines 23 and a plurality of second bend connection lines 24. The first bend connection lines 23 and the second bend connection lines 24 may extend along the second direction Y. The first bend connection lines 23 may be electrically connected with the first data fan-out lines 21, and the second bend connection lines 24 may be electrically connected with the second data fan-out lines 22. An arrangement order of a plurality of first bend connection lines 23 and a plurality of second bend connection lines 24 along the first direction X may be consistent with an arrangement order of a plurality of first data fan-out lines 21 and a plurality of second data fan-out lines 22 along the first direction X.

In some examples, as shown in FIG. 4, the second fan-out area 203 may include a plurality of third data fan-out lines 25, a plurality of fourth data fan-out lines 26 and a plurality of lead transfer lines 27. The fourth data fan-out lines 26 may be electrically connected with the second bend connection lines 24. The third data fan-out lines 25 may be electrically connected with the first bend connection lines 23. The third data fan-out lines 25 and the fourth data fan-out lines 26 may extend to the first circuit area.

In some examples, as shown in FIG. 4, the third fan-out area may include a plurality of fifth data fan-out lines 29 and a plurality of sixth data fan-out lines 28. The fifth data fan-out lines 29 may be electrically connected with the third data fan-out lines 25, and the sixth data fan-out lines 28 may be electrically connected with the fourth data fan-out lines 26. The fifth data fan-out lines 29 and the sixth data fan-out lines 28 may extend to the driver chip area 206 to electrically connect with connection pins of the driver chip area 206 and subsequently with the integrated circuit.

In this example, the first data lead wire may include the first data fan-out line 21, the first bend connection line 23, the third data fan-out line 25 and the fifth data fan-out line 29. The second data lead wire may include the second data fan-out line 22, the second bend connection line 24, the fourth data fan-out line 26 and the sixth data fan-out line 28.

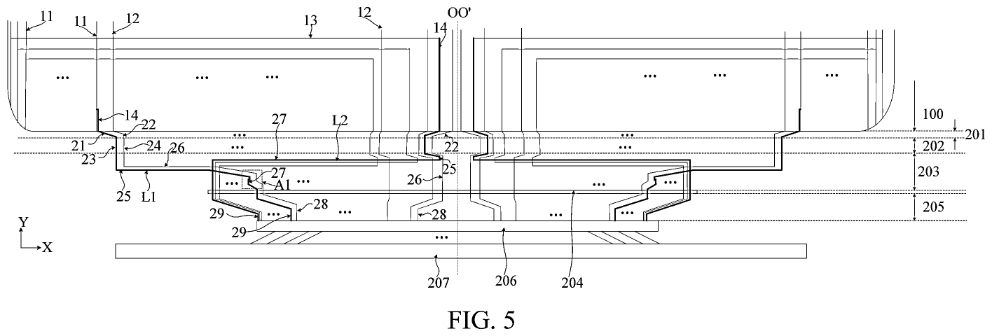

FIG. 5 is an example of a wiring diagram of a display substrate according to at least one embodiment of the present disclosure. In some examples, taking a left area of the first centerline OO′ as an example, as shown in FIG. 5, a first data lead wire L1 is closest to the edge of the display substrate, and a first data lead wire L2 is closest to the first centerline OO′. Remaining first data lead wires are located between the first data lead wires L1 and L2.

In some examples, as shown in FIG. 5, in the first area of the display region 100, a first data line 11 to which the first data lead wire L1 is electrically connected is located on a side close to the first centerline OO′ of the first data line 11 to which the first data lead wire L2 is electrically connected, a plurality of first data lines 11 are provided on a side away from the first centerline OO′ of the first data line 11 to which the first data lead wire L1 is electrically connected, and a plurality of second data lines 12 and a plurality of second data connection lines 14 are provided on a side close to the first centerline OO′.

In some examples, as shown in FIG. 5, in the second fan-out area 203, the third data fan-out line 25 of the first data lead wire L2 may be electrically connected with the lead transfer line 27, and the third data fan-out line 25 of the first data lead wire L2 may be electrically connected with a fifth data fan-out line 29 close to the edge of the first bezel region through the lead transfer line 27 extending at least in the first direction X. The third data fan-out line 25 of the first data lead wire L1 may be electrically connected with the lead transfer line 27, and the third data fan-out line 25 of the first data lead wire L1 may be electrically connected with a fifth data fan-out line 29 away from the edge of the first bezel region through the lead transfer line 27 extending at least in the first direction X. An order of the plurality of first data lead wires in the first fan-out area 201, the bending area 202, and an area of the second fan-out area 203 close to the bending area 202 is opposite to an order of the plurality of first data lead wires in an area of the second fan-out area 203 close to the first circuit area 204, and the third fan-out area 205. The plurality of lead transfer lines 27 may be substantially symmetrical with respect to the first centerline OO′.

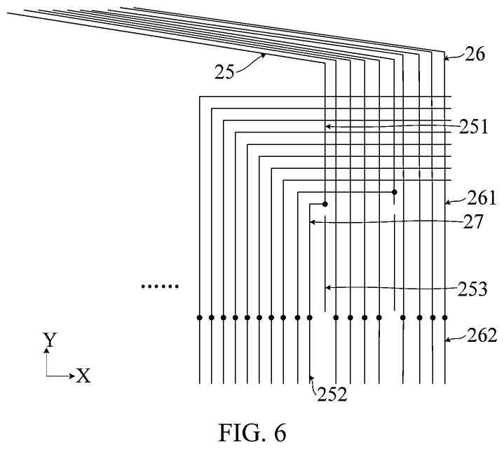

FIG. 6 is a local wiring diagram of a second fan-out area according to at least one embodiment of the present disclosure. FIG. 6 is a local wiring diagram of an area A1 in FIG. 5. In some examples, as shown in FIG. 6, the third data fan-out line 25 of the second fan-out area may include a first lead wire 251 and a second lead wire 252. The first lead wire 251 and the second lead wire 252 may be electrically connected through the lead transfer line 27. The lead transfer line 27 may extend in the first direction X at first, and then extend in the second direction Y to a side away from the display region. The lead transfer line 27 may be of a broken line type. A second lead wire 252 of a third data fan-out line 25 may be located on a side of the first lead wire 251 away from the first centerline in the first direction X. A first dummy trace 253 is also provided in an extending direction of the first lead wire 251 in the second direction Y, and the first dummy trace 253 is disconnected from the first lead wire 251. Wiring uniformity can be ensured by providing the first dummy trace 253.

In some examples, as shown in FIG. 6, the fourth data fan-out line 26 of the second fan-out area may include a third lead wire 261 and a fourth lead wire 262. The third lead wire 261 may be electrically connected with the fourth lead wire 262. For example, the third lead wire 261 may be electrically connected to the fourth lead wire 262 through a connection electrode. However, the embodiment is not limited thereto. For example, the third and fourth lead wires 261 and 262 may be in an integral structure. Alternatively, the third lead wire 261 may be electrically connected directly with the fourth lead wire 262. A plurality of second lead wires 252 may be located on a side of a plurality of fourth lead wires 262 close to the edge of the first bezel region in the first direction X.

In some examples, as shown in FIGS. 4 to 6, an arrangement order of a plurality of first lead wires 251 and third lead wires 261 of a plurality of fourth data fan-out lines 26 along the first direction X may be consistent with an arrangement order of a plurality of first bend connection lines 23 and a plurality of second bend connection lines 24 along the first direction X, and an arrangement order of a plurality of second lead wires 252 and fourth lead wires 262 of a plurality of fourth data fan-out lines 26 along the first direction X may be consistent with an arrangement order of a plurality of first data lines 11 and a plurality of second data lines 12 in the display region 100. In the present example, the jump wire interconnection can be performed on the third data fan-out line 25 by the lead transfer line 27, and a transmission order of the data signals can be adjusted so that the transmission order of the data signal is consistent with the arrangement order of the first data lines and the second data lines in the display region, so as to adapt to a conventional integrated circuit.

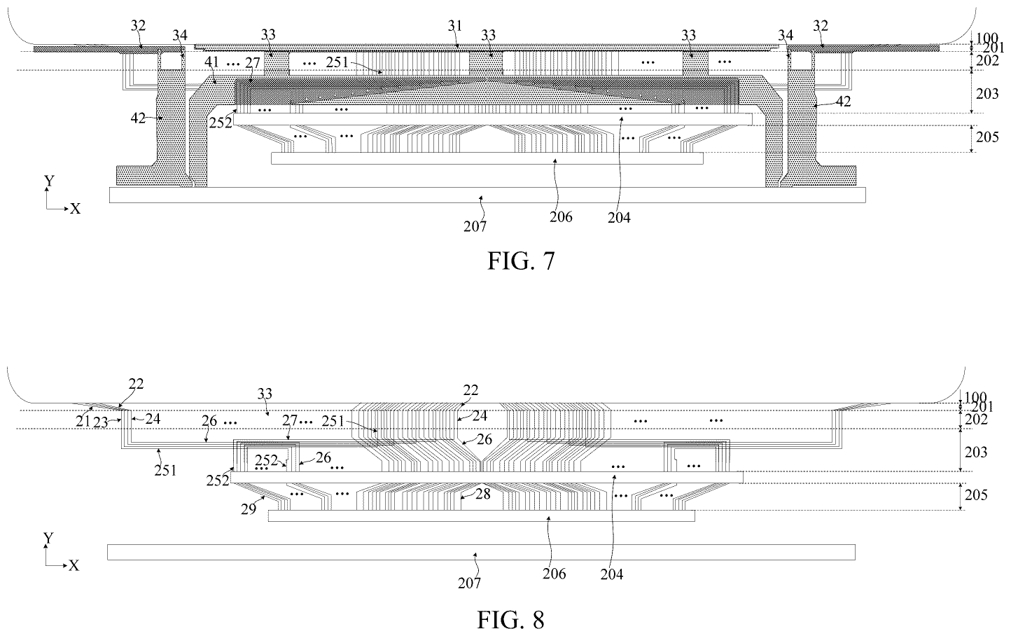

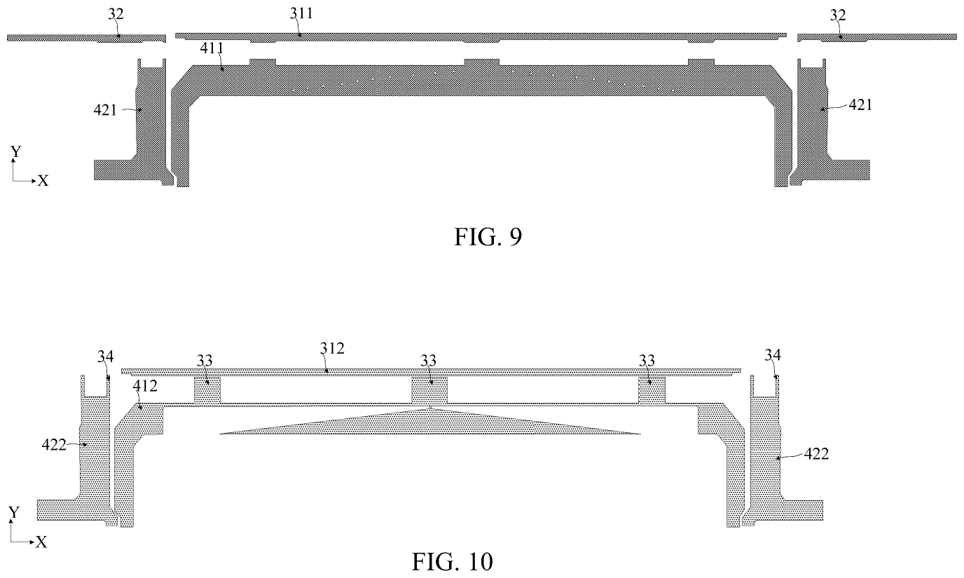

FIG. 7 is a partial schematic diagram of a first bezel region according to at least one embodiment of the present disclosure. FIG. 8 is a schematic diagram of a first data lead wire and a second data lead wire in FIG. 7. In FIGS. 7 and 8, only several first data lead wires and second data lead wires are illustrated as examples. FIG. 9 is a partial schematic diagram of a first source-drain metal layer in FIG. 7. FIG. 10 is a partial schematic diagram of a second source-drain metal layer in FIG. 7.

In some examples, as shown in FIG. 7, the first bezel region may be further provided with first power lines 41 and second power lines 42. At least part of the first power line 41 and at least part of the second power line 42 may be located in the second fan-out area 203. The first power line 41 may extend from the second fan-out area 203 in the second direction Y, bypassing the first circuit area 204 and the driver chip area 206, to the bonding pin area 207, so as to be electrically connected with a first power supply pin within the bonding pin area 207. The second power line 42 may be located on opposite sides of the first power line 41 in the first direction X. For example, the second power line 42 may be substantially symmetrical about the first centerline extending along the second direction Y. The second power line 42 may extend from the second fan-out area 203 to the bonding pin area 207 in the second direction Y, and be electrically connected with a second power supply pin within the bonding pin area 207. For example, the first power line 41 may be configured to continuously provide a high-level signal, and the second power line 42 may be configured to continuously provide a low-level signal.

In some examples, as shown in FIGS. 7 and 8, the lead transfer line 27 may be located in the second fan-out area 203, and both ends of the lead transfer line 27 may be electrically connected to the first lead wire 251 and the second lead wire 252, respectively. Orthographic projections of a plurality of lead transfer lines 27 on the base substrate may be overlapped with orthographic projections of the first power lines 41 on the base substrate. The orthographic projections of the first power lines 41 on the base substrate may be overlapped with orthographic projections of a plurality of first lead wires 251 on the base substrate. An orthographic projection of a connection position of the lead transfer line 27 to the second lead wire 252 on the base substrate may be not overlapped with the orthographic projections of the first power line 41 on the base substrate.

In some examples, as shown in FIGS. 7 and 8, the first lead wire 251 away from the edge of the first bezel region along the first direction X may be electrically connected with the lead transfer line 27 close to the bending area 202, and the first lead wire 251 close to the edge of the first bezel region along the first direction X may be electrically connected with the lead transfer line 27 away from the bending area 202.

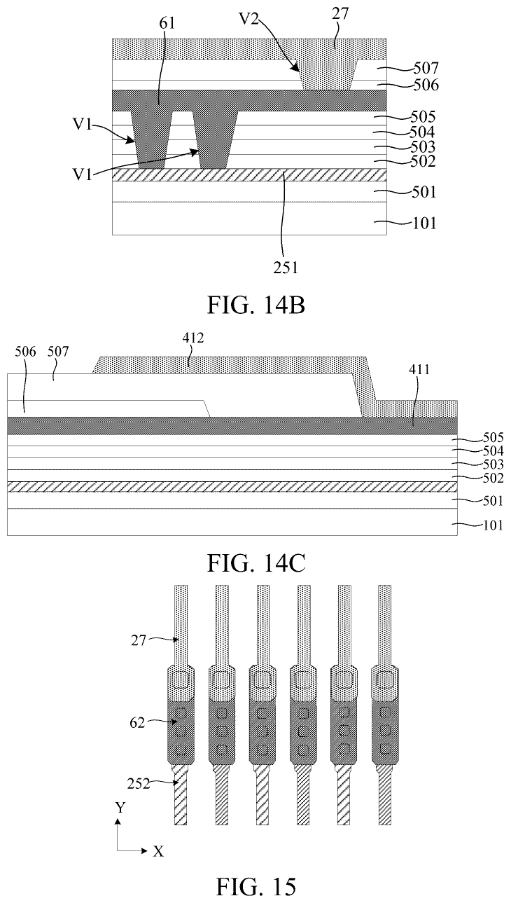

In some examples, as shown in FIG. 7, the first fan-out area 201 may further include a first power supply connection line 31 and a second power supply connection line 32. The second power supply connection line 32 may be located on opposite sides of the first power supply connection line 31 in the first direction X. The second power supply connection line 32 may extend along the edge of the display region 100 to the second bezel region, and be electrically connected with the bezel power supply lead wire in the second bezel region. As shown in FIG. 9, the second power supply connection line 32 may be located in the first source-drain metal layer. The first power supply connection line 31 may be electrically connected with a plurality of high-potential power lines in the display region so as to provide a high-potential power signal to a pixel circuit of a plurality of sub-pixels in the display region. In some examples, the first power supply connection line 31 may include a fifth trace 311 and a sixth trace 312 which are stacked. The fifth trace 311 may be located in the first source-drain metal layer and the sixth trace 312 may be located in the second source-drain metal layer. In some examples, the fifth trace 311 may have a plurality of first vent holes, the sixth trace 312 may have a plurality of second vent holes, and the orthographic projections of the first vent holes and the second vent holes on the base substrate may be rectangular, such as a rounded rectangle. The orthographic projections of the second vent holes on the base substrate may be overlapped with the orthographic projection of the first vent holes on the base substrate. The fifth trace provided with the plurality of first vent holes facilitates the gas discharge of the seventh insulation layer (such as a seventh insulation layer 507 in FIGS. 14A to 14C) during a manufacturing process, and the sixth trace 312 provided with the plurality of second vent holes facilitates the gas discharge of the eighth insulation layer (not shown) during the manufacturing process to prevent film explosion. The fifth trace 311 may be electrically connected with the sixth trace 312 through a plurality of vias opened in the seventh insulation layer. However, the embodiment is not limited thereto.

In some examples, as shown in FIGS. 7 to 10, the bending area 202 may further include a plurality (e.g. three) of third power supply connection lines 33 and a plurality (e.g. four) of fourth power supply connection lines 34. The third power supply connection lines 33 and the fourth power supply connection lines 34 may be in a same layer structure, for example all of them are located in the second source-drain metal layer. The third power supply connection line 33 may be electrically connected with the fifth trace 311 of the first power supply connection line 31. The fourth power supply connection line 34 may be electrically connected to the second power supply connection line 32.

In some examples, as shown in FIGS. 7 to 10, the first power line 41 may include a first trace 411 and a second trace 412 which are stacked. For example, the first trace 411 may be located in the first source-drain metal layer and the second trace 412 may be located in the second source-drain metal layer. The first trace 411 is electrically connected with the second trace 412. The second trace 412 and the third power supply connection line 33 may be in an integral structure. The second power line 42 may include a third trace 421 and a fourth trace 422 which are stacked. For example, the third trace 421 may be located in the first source-drain metal layer and the fourth trace 422 may be located in the second source-drain metal layer. The third and fourth traces 421 and 422 may be electrically connected. The fourth trace 422 and the fourth power supply connection line 34 may be in an integral structure. However, the embodiment is not limited thereto.

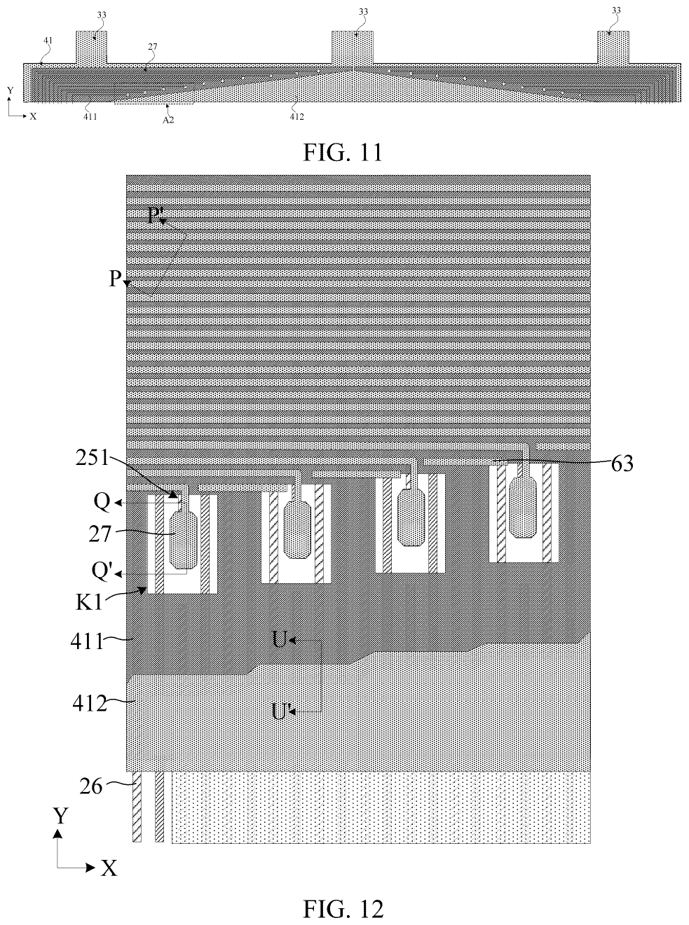

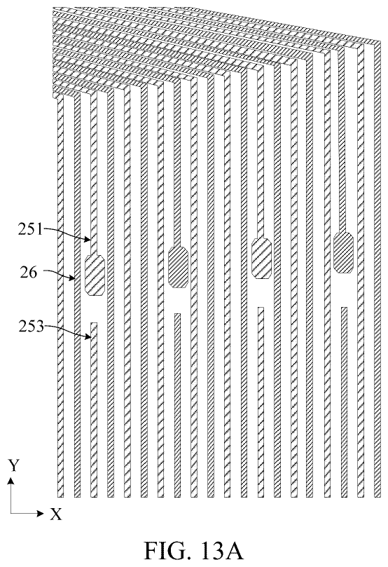

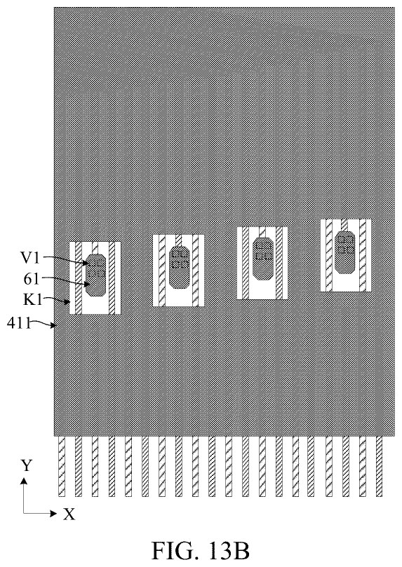

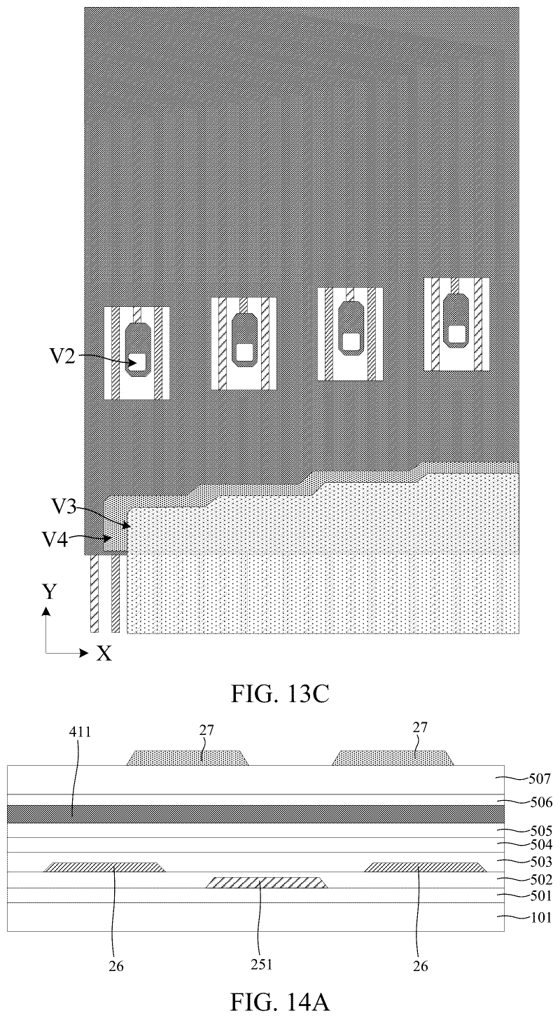

FIG. 11 is a partial schematic view of the bending area and the second fan-out area in FIG. 7. FIG. 12 is a partially enlarged view of an area A2 in FIG. 11. FIG. 13A is a partially enlarged view of the first fan-out area in FIG. 12, after the second gate metal layer is formed. FIG. 13B is a partially enlarged view of the second fan-out area in FIG. 12, after the first source-drain metal layer is formed. FIG. 13C is a partially enlarged view of the second fan-out area in FIG. 12, after the seventh insulation layer (such as the seventh insulation layer 507 in FIGS. 14A to 14C) is formed. FIG. 14A is a partially enlarged view along a P-P′ direction in FIG. 12. FIG. 14B is a partially enlarged view along a Q-Q′ direction in FIG. 12. FIG. 14C is a partially enlarged view along a U-U′ direction in FIG. 12.

In some examples, as shown in FIGS. 12 to 13A, in the second fan-out area, the first lead wire 251 of the third data fan-out line may be interposed between a plurality of fourth data fan-out lines 26 in the first direction X. For example, one first lead wire 251 may be arranged at intervals of four fourth data fan-out lines 26. The second fan-out area further includes a first dummy trace 253 aligned with the first lead wire 251 in the second direction Y. The first lead wire 251 and the first dummy trace 253 are in a same layer structure, and they are disconnected. For example, the first dummy traces 253 may extend along the second direction Y to the edges of the second fan-out area and the first circuit area. Alternatively, the first dummy trace 253 may extend along the second direction Y to a starting position of the second lead wire 252. The first dummy trace 253 is disconnected from the second lead wire 252, and is not electrically connected. By providing the first dummy trace 253, the wiring uniformity of the second fan-out area can be ensured. Two adjacent traces of the plurality of first lead wires 251 and the plurality of fourth data fan-out lines 26 may be located in different conductive layers. For example, as shown in FIG. 14A, a first lead wire 251 may be located in the first gate metal layer, and two fourth data fan-out lines 26 close to the first lead wire 251 may be located in the second gate metal layer. In this example, the first lead wire 251 and the fourth data fan-out lines 26 may be arranged using two conductive layers, and adjacent traces are located in different conductive layers, so that a compact arrangement of adjacent traces can be achieved, which is beneficial to reduce an arrangement space of traces, and interference between adjacent traces can be reduced.

In some examples, as shown in FIGS. 12 to 13B, the first trace 411 of the first power line may have a plurality of openings K1 in the second fan-out area. For example, an orthographic projection of the opening Kl on the base substrate may be a rectangle, such as a rounded rectangle. In the first direction X, a distance between the plurality of openings and the bending area can be gradually reduced in a direction from the edge to the center of the first bezel region. A first connection electrode 61 may be provided in the opening K1 of the first trace 411. An orthographic projection of the first connection electrode 61 on the base substrate may be located within the opening K1, and is not overlapped with an orthographic projection of the first trace 411 on the base substrate. The first traces 411 and the first connection electrodes 61 may be in a same layer structure, for example, in the first source-drain metal layer. As shown in FIG. 14B, the first connection trace 61 may be electrically connected to the first lead wires 251 located in the first gate metal layer (or the second gate metal layer) through a plurality (e.g. four) of first vias V1 opened in a fifth insulation layer 505. The fifth insulation layer 505, a fourth insulation layer 504, a third insulation layer 503, and a second insulation layer 502 in the first vias V1 may be removed to expose a surface of the first lead wire 251.

In some examples, as shown in FIGS. 12 to 13C, in the second fan-out area, the second trace 412 of the first power line and the lead transfer line 27 may be in a same layer structure, for example, may be located in the second source-drain metal layer. The lead transfer line 27 may extend at least along the first direction X, for example, toward the side of the second lead wire in the first direction X at first, and then toward the side away from the display region in the second direction Y, until electrically connected to the second lead wire. The lead transfer line 27 may be electrically connected to the first connection electrode 61 located in the first source-drain metal layer through a second via V2. As shown in FIG. 14B, a sixth insulation layer 506 and a seventh insulation layer 507 in the second via V2 may be removed to expose a surface of the first connection electrode 61. The orthographic projection of the lead transfer line 27 on the base substrate is overlapped with the orthographic projection of the first trace 411 of the first power line on the base substrate. In this example, the influence on the first power line can be minimized in a process of interconnecting the first lead wire by a punch-opening design of the first trace 411 of the first power line so that an orthographic projection of the connection position of the lead transfer line 27 to the first lead wire 251 is located in the opening.

In some examples, as shown in FIG. 12, the second fan-out area may further include a plurality of second dummy traces 63 extending along the first direction X. The second dummy trace 63 may be located between adjacent lead transfer lines 27 in the first direction X. In the second direction Y, the second dummy trace 63 may be close to the lead transfer line 27, and the second dummy trace 63 may be located on a side of the lead transfer line 27 away from the display region. By providing the second dummy traces 63, arrangement uniformity of the lead transfer lines of the second fan-out area can be achieved, and influence of the manufacturing process on the lead transfer line located at the edges can be improved.

In some examples, as shown in FIGS. 12 and 14A, a plurality of lead transfer lines 27 may be located on a side of the first trace 411 of the first power line away from the base substrate 101, and a plurality of first lead wires 251 and fourth data fan-out lines 26 may be located on a side of the first trace 411 close to the base substrate 101. Using the first trace 411 of the first power line, the lead transfer line 27 can be isolated from the plurality of first lead wires 251 and the fourth data fan-out lines 26, and cross-talk between the traces can be effectively prevented. Taking data signals received by the red sub-pixel and the blue sub-pixel as AC signals and a data signal received by the green sub-pixel as a DC signal as an example, the first power line is used to isolate the lead transfer line, so that influence of the AC signals transmitted by the lead transfer line on the DC signal transmitted below the first trace can be isolated, and the influence of the AC signals transmitted below the first trace on the DC signal transmitted by the lead transfer line can also be isolated.

In some examples, as shown in FIGS. 12 and 14A, a seventh insulation layer 507 and a sixth insulation layer 506 may be provided between the lead transfer line 27 and the first trace 411 of the first power line. For example, the seventh insulation layer 507 may be an organic insulation layer, and the sixth insulation layer 506 may be an inorganic insulation layer. By providing the seventh insulation layer 507, a planarization effect can be achieved, which is beneficial to increase a process yield, and by adding a dielectric layer between the lead transfer line 27 and the first trace 411, it is beneficial to reduce parasitic capacitance therebetween and reduce the influence therebetween.

In some examples, as shown in FIGS. 12, 13C, and 14C, the sixth insulation layer 506 may be provided with a first groove V4, and the sixth insulation layer 506 within the first groove V4 may be removed. The seventh insulation layer 507 may be provided with a second groove V3, and the seventh insulation layer 507 within the second groove V3 may be removed. In this example, an orthographic projection of the first groove V4 on the base substrate 101 may be within the orthographic projection range of the first trace 411 on the base substrate 101, an orthographic projection of the second groove V3 on the base substrate 101 may be partially overlapped with the orthographic projection of the first trace 411 on the base substrate 101. For example, the seventh insulation layer 507 in an area on a side of the first trace 411 away from the display region may be removed. In an area where the first power line is located, an orthographic projection of the second trace 412 of the first power line on the base substrate 101 may be overlapped with an orthographic projection of an edge of the sixth insulation layer 506 on the base substrate 101, so as to cover the boundary of the sixth insulation layer 506. The orthographic projection of the second trace 412 on the base substrate 101 may be overlapped with an orthographic projection of an edge of the seventh insulation layer 507 on the base substrate 101. The second trace 412 and the first trace 411 may be in direct contact at an overlapping area of the first groove V4 and the second groove V3. In this example, the first power line employs a double-layer wiring design, and the second trace can cover part of the boundaries of reserved seventh insulation layer and the sixth insulation layer, which can effectively reduce risk of film peeling.

In some examples, as shown in FIGS. 7 to 11, the first power line employs a single-layer routing design in an area where the first lead wire 251 is interconnected with the lead transfer line 27, the first power line may employ a double-layer wiring design in the remaining areas, and the first and second traces 411 and 412 may at least partially be in direct contact.

In some examples, as shown in FIGS. 7 to 10, the second power line 42 may employ a double-layer wiring design (i.e. including the third trace 421 and the fourth trace 422 which are stacked). At least part of the third and fourth traces 421 and 422 may be in direct contact. At edges of orthographic projections of the third and fourth traces 421 and 422 on the base substrate, the orthographic projection of the fourth traces 422 on the base substrate may cover an edge of the sixth insulation layer and cover at least a portion of an edge of the seventh insulation layer to effectively reduce the risk of film peeling. A connection mode of the third and fourth traces of the second power line may be substantially the same as a connection mode of the first and second traces of the first power line.

FIG. 15 is a schematic diagram of connection between the lead transfer line and the second lead wire according to at least one embodiment of the present disclosure. In some examples, as shown in FIG. 15, the lead transfer line 27 located in the second source-drain metal layer may be electrically connected to the second connection electrode 62 located in the first source-drain metal layer through the via opened in the seventh and sixth insulation layers. The second connection electrode 62 may be electrically connected to the second lead wire 252 located in the first gate metal layer through a via opened from the fifth insulation layer to the second insulation layer. Alternatively, the second connection electrode 62 may be electrically connected to the second lead wire 252 located in the second gate metal layer through a via opened from the fifth insulation layer to the third insulation layer. An orthographic projection of a connection position of the lead transfer line 27 to the second lead wire 252 on the base substrate may be not overlapped with the orthographic projection of the first power line on the base substrate. The connection position of the lead transfer line 27 to the second lead wire 252 may be located on a side of the first power line away from the bending area. However, the embodiment is not limited thereto. In other examples, the connection position of the lead transfer line 27 and the second lead wire 252 may be located on a side of the first power line close to the bending area. As another example, the first trace of the first power line can be further provided with a plurality of openings, and the second connection electrode can be located in the openings to achieve electrical connection with the second lead wire and the lead transfer line.

The structure of the display substrate is illustrated below with reference to a manufacturing process of the display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” mentioned in the present disclosure means that A and B are formed simultaneously through a same patterning process, or surfaces of A and B close to a base substrate have basically a same distance from the base substrate, or the surfaces of A and B close to the base substrate are in direct contact with a same film layer. A “thickness” of a film layer is a dimension of the film layer in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.

(1) A base substrate is provided. In some examples, the base substrate may be a flexible base substrate. For example, the flexible base substrate may include a first flexible material layer, a first inorganic material layer, a semiconductor layer, a second flexible material layer and a second inorganic material layer which are stacked on a glass carrier plate. The first flexible material layer and the second flexible material layer may be made of polyimide (PI), polyethylene terephthalate (PET) or surface-treated polymer soft film, etc. The first inorganic material layer and the second inorganic material layer may be made of silicon nitride (SiNx) or silicon oxide (SiOx), etc. to improve water and oxygen resistance of the underlay substrate. The first inorganic material layer and the second inorganic material layer may also be referred to as barrier layers. The semiconductor layer may be made of amorphous silicon (a-si). However, the embodiment is not limited thereto.

(2) A first semiconductor layer is formed. In some examples, a first semiconductor thin film is deposited on the base substrate, and the first semiconductor thin film is patterned through a patterning process to form the first semiconductor layer disposed on the base substrate. For example, the first semiconductor layer may include an active layer of low temperature poly-silicon thin film transistor of a pixel circuit located in a display region.

(3) A first gate metal layer is formed. In some examples, a first insulation thin film and a first metal thin film are deposited sequentially on the base substrate on which the aforementioned pattern is formed, and the first metal thin film is patterned through a patterning process to form a first insulation layer and a first gate metal layer disposed on the first insulation layer. For example, the first gate metal layer may include, at least, both a gate of the low-temperature poly-silicon thin film transistor and one of electrodes of a storage capacitor of the pixel circuit located in the display region, a plurality of first data fan-out lines and a plurality of second data fan-out lines located in a first fan-out area located in a first bezel region, a plurality of third data fan-out lines and a plurality of fourth data fan-out lines located in a second fan-out area, and a plurality of fifth data fan-out lines and a plurality of sixth data fan-out lines located in a third fan-out area.

(4) A second gate metal layer is formed. In some examples, a second insulation thin film and a second metal thin film are deposited sequentially on the base substrate on which the aforementioned patterns are formed, and the second metal thin film is patterned through a patterning process to form a second insulation layer and a second gate metal layer disposed on the second insulation layer. For example, the second gate metal layer may include, at least, another electrode of the storage capacitor of the pixel circuit located in the display region, the plurality of first data fan-out lines and the plurality of second data fan-out lines located in the first fan-out area located in the first bezel region, the plurality of third data fan-out lines and the plurality of fourth data fan-out lines located in the second fan-out area, and the plurality of fifth data fan-out lines and the plurality of sixth data fan-out lines located in the third fan-out area. In this example, adjacent traces of the plurality of first data fan-out lines and the plurality of second data fan-out lines of the first fan-out area may be located in different conductive layers. Adjacent traces of the plurality of third data fan-out lines and the plurality of fourth data fan-out lines of the second fan-out area may be located in different conductive layers. Adjacent traces of the plurality of fifth data fan-out lines and the plurality of sixth data fan-out lines of the third fan-out area may be located in different conductive layers.

(5) A second semiconductor layer is formed. In some examples, a third insulation thin film and a second semiconductor thin film are sequentially deposited on the base substrate on which the aforementioned patterns are formed, and the second semiconductor thin film is patterned through a patterning process to form a third insulation layer and a second semiconductor layer disposed on the third insulation layer. For example, the second semiconductor layer may include a gate of an oxide thin film transistor located in the pixel circuit of the display region.

(6) A third gate metal layer is formed. In some examples, a fourth insulation thin film and a third metal thin film are deposited sequentially on the base substrate on which the aforementioned patterns are formed, and the third metal thin film is patterned through a patterning process to form a fourth insulation layer and a third gate metal layer disposed on the fourth insulation layer. For example, the third gate metal layer may include, at least, the gate of the oxide thin film transistor located in the pixel circuit of the display region.

(7) A first source-drain metal layer is formed. In some examples, a fifth insulation layer is deposited on the base substrate on which the aforementioned patterns are formed, and a fifth insulation layer is formed by a patterning process, then a fourth metal thin film is deposited, and a first source-drain metal layer is formed by a patterning process. The fifth insulation layer of the display region may be provided with a plurality of vias that may expose a surface of the first semiconductor layer, the first gate metal layer, the second gate metal layer, the third gate metal layer or the second semiconductor layer, for example. For example, at least part of a first insulation layer to a fifth insulation layer of a bending area of the first bezel region is removed. A fifth insulation layer of the second fan-out area of the first bezel region is provided with a plurality of vias that may expose a surface of the first gate metal layer or the second gate metal layer, for example. For example, the first source-drain metal layer may include a plurality of connection electrodes and a plurality of first data connection lines located in the pixel circuit of the display region, a fifth trace of a first power supply connection line and a second power supply connection line located in the first fan-out area of a first bezel region, a plurality of first connection electrodes, a plurality of second connection electrodes, a first trace of a first power line and a third trace of a second power line located in the second fan-out area.

(8) A second source-drain metal layer is formed. In some examples, a sixth insulation layer is deposited on the base substrate on which the aforementioned patterns are formed, and the sixth insulation layer is formed by a patterning process. Subsequently, a seventh insulation thin film is coated and a seventh insulation layer is formed by a patterning process. Subsequently, a fifth metal thin film is deposited, and a second source-drain metal layer is formed by a patterning process. Subsequently, an eighth insulation thin film is coated and an eighth insulation layer is formed by a patterning process. In some examples, a second source-drain metal layer may include a plurality of first data lines, a plurality of second data lines, and a plurality of second data connection lines located in the display region, a sixth trace of the first power supply connection line located in the first fan-out area of the first bezel region, a first bend connection line, a second bend connection line, a third power supply connection line, and a fourth power supply connection line located in the bending area, and a lead transfer line, a second trace of the first power line, and a fourth trace of the second power line located in the second fan-out area.

At that point, manufacturing of a circuit structure layer can be accomplished in the display region of the base substrate.

(9) A light emitting structure layer is formed. In some examples, a first conductive thin film is deposited on the base substrate on which the aforementioned patterns are formed, and the first conductive thin film is patterned through a patterning process to form an anode layer. The anode layer includes anodes of a plurality of light emitting elements. The anodes can be electrically connected with the pixel circuit through a via opened in the eighth insulation layer. Subsequently, a pixel definition thin film is coated and a pixel definition layer is formed by masking, exposure and development processes. A pixel definition layer of the display region is provided with a plurality of pixel openings exposing the anode layer. Subsequently, an organic light emitting layer and a cathode layer are sequentially formed in the display region. An organic light emitting layer is formed in the pixel opening, achieving connection between the organic light emitting layer and the anode. A cathode is formed on the pixel definition layer and connected with the organic light emitting layer.

(10) An encapsulation structure layer is formed. In some examples, an encapsulation structure layer may include a stacked structure of inorganic material/organic material/inorganic material.

In some examples, a material of the first semiconductor layer may include poly-silicon. A material of the second semiconductor layer may include metal oxide. The first gate metal layer, the second gate metal layer, the third gate metal layer, the first source-drain metal layer and the second source-drain metal layer may be made of a metal material, such as any one or more of silver (Ag), copper (Cu), aluminum (Al) and molybdenum (Mo), or an alloy material of the above metals, such as AlNd alloy or MoNb alloy, which may of a single-layer structure or a multi-layer composite structure, such as Mo/Cu/Mo. The first insulation layer to the sixth insulation layer may be any one or more of silicon oxide (SiOx), silicon nitride (SiNx), and silicon oxynitride (SiON), and may be in a single layer, multiple layers, or a composite layer. The seventh insulation layer and the eighth insulation layer may be made of an organic material, such as polyimide, acrylic, or polyethylene terephthalate. The pixel definition layer may be made of an organic material, such as polyimide, acrylic, or polyethylene terephthalate. The anode layer may be made of a reflective material such as a metal, and the cathode may be made of a transparent conductive material. However, the embodiment is not limited thereto.

A structure and a manufacturing process of the display substrate of this embodiment are merely illustrative. In some examples, a corresponding structure may be changed and a patterning process may be added or reduced according to actual needs. The manufacturing process of the exemplary embodiment may be implemented using an existing mature manufacturing device, and may be compatible well with an existing manufacturing process, simple in process implementation, easy to implement, high in a production efficiency, low in a production cost, and high in yield.

The display substrate provided in this embodiment can adjust transmission order of the data signals by using the lead transfer line, so that the supply oder of the data signals or the test data signals in the first bezel region is consistent with an order of the first data lines and the second data lines in the display region, and the influence on the first power line is reduced. Moreover, the routing manner of the data lead wire in this example is beneficial to improve the resistance abrupt change of the traces. In addition, the first power line isolates the data fan-out line and the lead transfer line, thereby effectively preventing mutual cross-talk between the data signals.

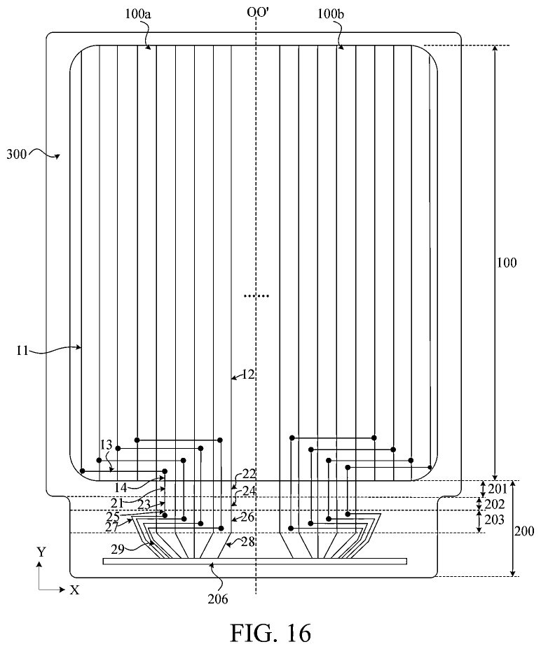

FIG. 16 is another wiring diagram of a display substrate according to at least one embodiment of the present disclosure. In some examples, as shown in FIG. 16, in either the first area 100a or the second area 100b, the second data connection line 14 to which the first data line 11 away from the first centerline OO′ is electrically connected may be located on a side away from the first centerline OO′ of the second data connection line 14 to which the first data line 11 close to the first centerline OO′ is electrically connected, in the first direction X. In this example, taking the first area 100a of the display region as an example, an arrangement order of the plurality of first data lines 11 from edge to center along the first direction X is consistent with an arrangement order of the second data connection lines 14 to which the plurality of first data lines 11 are interconnected from edge to center along the first direction X. The transferring mode of the first data line 11 shown in this example may be referred to as a positive sequence insertion mode.

In some examples, as shown in FIG. 16, in either the first area 100a or the second area 100b, a length of the second data connection line 14 to which the first data line 11 away from the first centerline OO′ is electrically connected may be less than a length of the second data connection line 14 to which the first data line 11 close to the first centerline OO′ is electrically connected, along the second direction Y. The first data connection line 13 to which the first data line 11 away from the first centerline OO′ is electrically connected may be located on a side close to a lower edge of the display region 100 of the first data connection line 13 to which the first data line 11 close to the first centerline OO′ is electrically connected, in the second direction Y.

In some examples, as shown in FIG. 16, the third data fan-out line 25 located in the second fan-out area 203 may include a first lead wire and a second lead wire, which may be electrically connected through the lead transfer line 27. The lead transfer line 27 electrically connected to the first lead wire close to the first centerline OO′ may be located, in the second direction Y, on the side away from the bending area 202 of the lead transfer line 27 electrically connected to the first lead wire away from the first centerline OO′. The lead transfer line 27 may be overlapped with the orthographic projection of the first power line on the base substrate, in the second fan-out area 203.

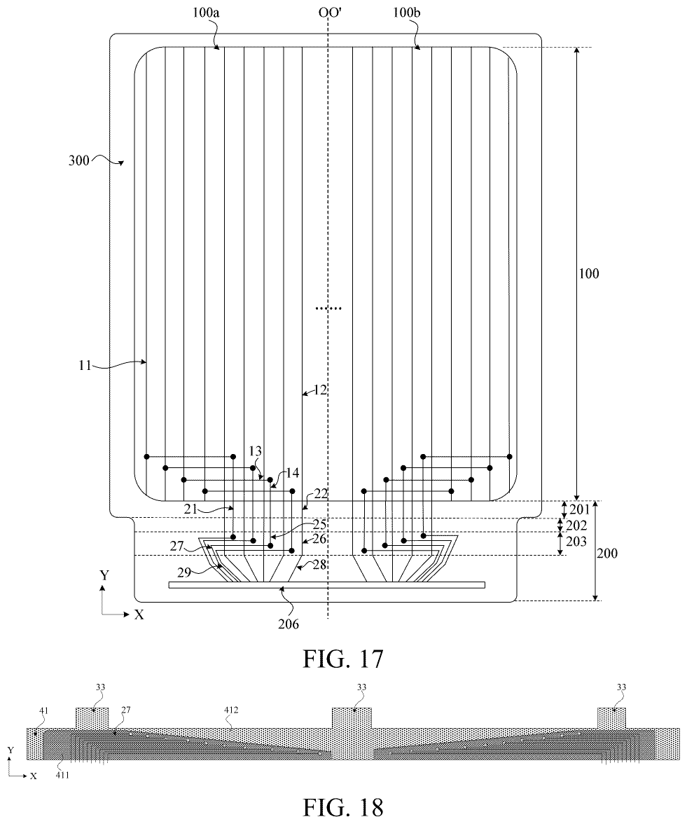

FIG. 17 is another wiring diagram of a display substrate according to at least one embodiment of the present disclosure. In some examples, as shown in FIG. 17, in either the first area 100a or the second area 100b, the length of the second data connection line 14 to which the first data line 11 away from the first centerline OO′ is electrically connected may be greater than the length of the second data connection line 14 to which the first data line 11 close to the first centerline OO′ is electrically connected, along the second direction Y. The first data connection line 13 to which the first data line 11 away from the first centerline OO′ is electrically connected may be located on a side away from a lower edge of the display region 100 of the first data connection line 13 to which the first data line 11 close to the first centerline OO′ is electrically connected, in the second direction Y. Remaining configuration of the display substrate of this embodiment is substantially the same as that of the embodiment shown in FIG. 16.

FIG. 18 illustrates schematically a partial view of the second fan-out area in FIG. 16 or FIG. 17. In some examples, as shown in FIGS. 16 to 18, the third data fan-out line 25 located in the second fan-out area 203 may include a first lead wire and a second lead wire, which may be electrically connected through the lead transfer line 27. The lead transfer line 27 electrically connected to the first lead wire close to the first centerline OO′ may be located, in the second direction Y, on the side away from the bending area 202 of the lead transfer line 27 electrically connected to the first lead wire away from the first centerline OO′. The transferring mode of the first data line shown in this example may be a positive sequence insertion mode. The lead transfer line 27 may be overlapped with the orthographic projection of the first power line 41 on the base substrate, in the second fan-out area 203. The first power line 41 may include a first trace 411 and a second trace 412. The first trace 411 may have a plurality of openings, an orthographic projection of the connection position of the lead transfer line 27 and the first lead wire on the base substrate can be located in the openings, without overlapping with the first trace 411. In an area where the lead transfer line 27 is not arranged, the first power line 41 may employ a double-layer wiring structure of the first wiring 411 and the second wiring 412.

With regard to other structure of the display substrate of the present embodiment, reference may be made to the description of the above embodiment, and will not be repeated here.

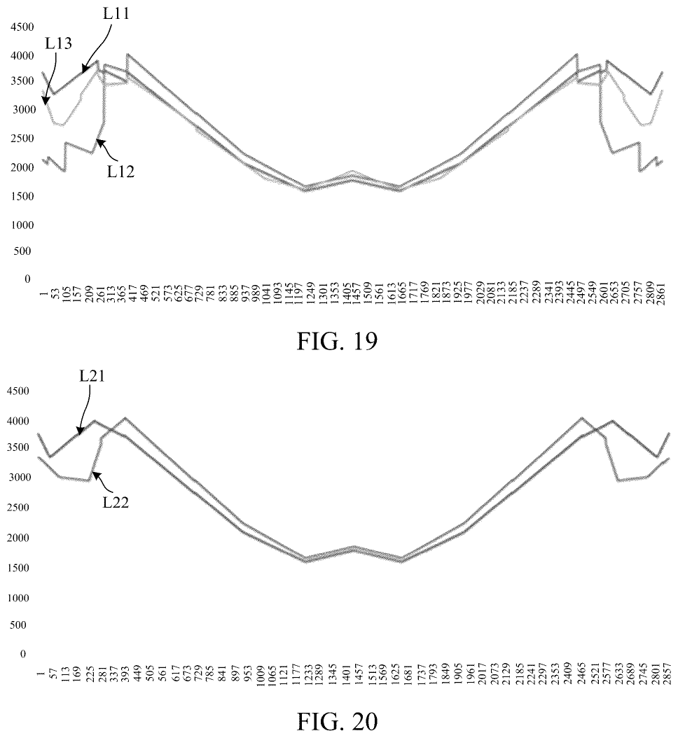

FIG. 19 is a graph showing resistance changes of the plurality of data lead wires in the first bezel region. FIG. 20 is a graph showing resistance changes of the plurality of data lead wires in the first bezel region after resistance compensation. An abscissa in FIGS. 19 and 20 indicates a serial number of the data lead wires in the first direction, and an ordinate indicates a resistance value.

In some examples, as shown in FIG. 19, a curve L11 indicates a resistance change of a data lead wire after the transferring is performed using a lead transfer line, in the display substrate using the reverse sequence insertion mode as shown in FIG. 4 in the first bezel region. A curve L12 shows a resistance change of the data lead wire after the transferring is performed through the lead transfer line, in the first bezel region of the display substrate using the positive sequence insertion mode as shown in FIG. 16 or FIG. 17. A curve L13 indicates a resistance change of the data lead wire after the display substrate using the reverse sequence insertion mode uses an updated integrated circuit instead of the lead transfer line in the first bezel region. As can be seen from FIG. 19, resistance jump, from small to large, is as follows: the curve L11, the curve L12 and the curve L13.

In some examples, as shown in FIG. 19, when performing resistance compensation, the curve L11 needs fewer points to be compensated, and the resistance difference is small (for example, only 166Ω), which is easy to compensate, and a required compensation space is small, which is beneficial to narrowing the lower frame of the display substrate. For the curve L12, since there is no jumper design for the first data lead wire through the lead transfer line, the first data lead wire is interspersed in the second data lead wire, and its position is scattered, which leads to a huge workload of resistance compensation. The curve L13 needs more points to be compensated, and the resistance difference is large (for example, the maximum difference is about 983Ω), so the compensation space is large.

In some examples, as shown in FIG. 20, a curve L21 indicates a resistance change of a data lead wire with resistance compensation after the transferring is performed through a lead transfer line, in the display substrate using the reverse sequence insertion mode as shown in FIG. 4 in the first bezel region. A curve L22 shows a resistance change of the data lead wire with resistance compensation after the transferring is performed through the lead transfer line, in the first bezel region of the display substrate in the positive sequence insertion mode as shown in FIG. 16 or FIG. 17. As can be seen from FIG. 20, transition of the curve L21 is smoother than transition of the curve L22. Therefore, the solution in which the display substrate using the reverse sequence insertion method in the first bezel region through transferring by using the lead transfer line is superior to the solution in which the display substrate using the positive sequence insertion mode in the first bezel region through transferring by using the lead transfer line. This embodiment is not limited to the resistance compensation method employed.

In some examples, the display substrate of the embodiment of the present disclosure may be applied to a display apparatus with a pixel circuit, such as an OLED, a quantum dot display (QLED), a light emitting diode display (Micro LED or Mini LED), or a Quantum Dot Light Emitting Diode display (QDLED), which is not limited here in the present disclosure.

A display apparatus is also provided in an embodiment of the present disclosure, which may include the aforementioned display substrate. In some examples, the display apparatus may be a mobile phone, a tablet computer, a television, a display, a laptop computer, a digital photo frame, a navigator, or any product or component with a display function, which is not limited in the embodiment of the present invention.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising a display region and a bezel region, wherein the bezel region comprises a first bezel region located on a side of the display region; the display region has a first boundary close to the first bezel region, the bezel region has a second boundary and a third boundary that are located on both sides of the first boundary in a first direction;
a plurality of sub-pixels located in the display region;
a plurality of first data lines, a plurality of second data lines, a plurality of first data connection lines and a plurality of second data connection lines located in the display region;
the plurality of first data lines and the plurality of second data lines configured to provide data signals to the plurality of sub-pixels; the plurality of first data connection lines extending along the first direction, the plurality of first data lines, the plurality of second data lines and the plurality of second data connection lines extending along a second direction, wherein the first direction intersects with the second direction; the plurality of first data lines electrically connected with the plurality of second data connection lines through the plurality of first data connection lines; the plurality of first data lines located on a side of the plurality of second data lines and the plurality of second data connection lines close to the second boundary or the third boundary, in the first direction;
a plurality of first data lead wires, a plurality of second data lead wires, a plurality of lead transfer lines and at least one first power line located in the first bezel region; the plurality of first data lead wires electrically connected with the plurality of second data connection lines, the plurality of second data lead wires electrically connected with the plurality of second data lines, and the at least one first power line configured to provide a power signal to the plurality of sub-pixels;
at least one of the plurality of first data lead wires comprising a first lead wire and a second lead wire, wherein the first lead wire is electrically connected with the second lead wire through the lead transfer line, the first lead wire is electrically connected with the second data connection line, the lead transfer line extends at least partially along the first direction, and the second lead wire is located on a side of the second data lead wire close to the second boundary or the third boundary in the first direction;
an orthographic projection of at least one of the plurality of lead transfer wires on the base substrate overlapped with an orthographic projection of the first power line on the base substrate.

2. The display substrate of claim 1, wherein the first power line comprises, at least, a first trace; wherein the first trace has a plurality of openings, and an orthographic projection of a connection position of the first lead wire with the lead transfer line on the base substrate is within an orthographic projection range of the openings on the base substrate.

3. The display substrate of claim 2, wherein at least part of segments of the first data lead wires and at least part of segments of the second data lead wires are located on a side of the first trace close to the base substrate, and the lead transfer lines are located on a side of the first trace away from the base substrate.

4. The display substrate of claim 2, wherein at least an organic insulation layer is provided between the lead transfer line and the first trace.

5. The display substrate of claim 2, wherein the first lead wire is electrically connected to the lead transfer line through a first connection electrode located within the opening, and an orthographic projection of the first connection electrode on the base substrate is not overlapped with an orthographic projection of the first trace on the base substrate, wherein the first connection electrode and the first trace are in a same layer structure.

6. (canceled)

7. The display substrate of claim 2, wherein orthographic projections of the first data lead wire and the second data lead wire on the base substrate are overlapped with an orthographic projection of the first trace on the base substrate.

8. The display substrate of claim 2, wherein the first power line further comprises a second trace located on a side of the first trace away from the base substrate, the second trace is electrically connected with the first trace, and an orthographic projection of the second trace on the base substrate is not overlapped with orthographic projection of the opening of the first trace on the base substrate.

9. The display substrate of claim 8, wherein the second trace and the lead transfer line are in a same layer structure.

10. The display substrate of claim 8, wherein at least one insulation layer is disposed between the first trace and the second trace, at least part of the first trace is in direct contact with the second trace, and the orthographic projection of the second trace on the base substrate covers at least part of a boundary of the at least one insulation layer, wherein the at least one insulation layer comprises an inorganic insulation layer and an organic insulation layer, wherein the inorganic insulation layer is located on a side of the organic insulation layer close to the base substrate.

11. (canceled)

12. The display substrate of claim 1, wherein the display substrate has a first centerline in the first direction, the plurality of first data lines are located on a side of the plurality of second data lines and the plurality of second data connection lines away from the first centerline, in the first direction, and the plurality of second lead wires are located on a side of the second data lead wires away from the first centerline, in the first direction.

13. The display substrate of claim 12, wherein the display region comprises a first area and a second area located on both sides of the first centerline; in the first area or the second area, a second data connection line to which a first data line away from the first centerline is electrically connected is located on a side close to the first centerline of a second data connection line to which a first data line close to the first centerline is electrically connected.

14. The display substrate of claim 12, wherein the display region comprises a first area and a second area located on both sides of the first centerline; in the first area or the second area, a second data connection line to which a first data line away from the first centerline is electrically connected is located on a side away from the first centerline of a second data connection line to which a first data line close to the first centerline is electrically connected.

15. The display substrate of claim 12, wherein a lead transfer line to which a first lead wire close to the first centerline is electrically connected is located on a side close to the display region of a lead transfer line to which a first lead wire away from the first centerline is electrically connected.

16. The display substrate of claim 12, wherein a lead transfer line to which a first lead wire close to the first centerline is electrically connected is located on a side away from the display region of a lead transfer line to which a first lead wire away from the first centerline is electrically connected.

17. The display substrate of claim 12, wherein the plurality of lead transfer lines are symmetrical with respect to the first centerline.

18. The display substrate of claim 1, wherein the first bezel region comprises, at least, a first fan-out area, a bending area, a second fan-out area, and a first circuit area disposed in sequence in a direction away from the display region; the first circuit area comprises, at least, a test circuit, and the first power line and the lead transfer line are at least located in the second fan-out area.

19. The display substrate of claim 18, wherein the first and second lead wires are located in the second fan-out area.

20. The display substrate of claim 19, wherein an orthographic projection of a connection position of the second lead wire with the lead transfer line on the base substrate is not overlapped with the orthographic projection of the first power line on the base substrate.

21. The display substrate of claim 19, wherein a connection position of the second lead wire and the lead transfer line is located on a side of the first power line away from the bending area.

22. A display apparatus, comprising a display substrate of claim 1.
